(19) United States
(12) Patent Application Publication
(10) Pub. No.: US 2007/0004105 A1
(43) Pub. Date: Jan. 4, 2007

(54) Method for fabricating semiconductor device

(76) Inventor: Ki-Won Nam, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/323,524

(22) Filed: Dec. 29, 2005

(30) Foreign Application Priority Data
Jun. 30, 2005 (KR) 2005-0058520

(51) Int. Cl. H01L 21/84; H01L 21/44

(52) U.S. Cl. 438/152; 438/682; 257/E21.438

(57) ABSTRACT

A method for fabricating a semiconductor device is provided. The method includes: forming a gate insulation layer on a substrate; forming a gate electrode on the gate insulation layer, wherein the gate electrode includes a pattern of a poly-silicon layer and a silicide layer on which a hard mask layer is superposed; recessing the silicide layer in a horizontal direction; and forming a thermal oxide layer on exposed portions of the substrate, the poly-silicon layer, and the silicide layer.

### FIELD OF THE INVENTION

The present invention relates to a method for fabricating a semiconductor device; and, more particularly, to a method for fabricating a semiconductor device capable of improving a processing yield and reliability of device operations by removing an excessively grown projection on a lateral wall of a silicide layer which is formed during a thermal oxidation process, wherein the thermal oxidation process is performed after a gate patterning process.

### DESCRIPTION OF RELATED ARTS

Recently, a large scale of integration in semiconductor devices have been greatly affected by the improvement of micro-pattern formation technology, and it is essential to micronize a photoresist pattern which is used as a mask in a wide variety of areas, i.e., in an etching process or an ion implantation process during a fabrication process of a semiconductor device.

Although a resolving power R of such photoresist pattern is closely related to a photoresist material itself or an adhesive power with a substrate, the resolving power R is primarily proportionate to a light source wave (X) of a photolithography device used in the process. Thus, the light source wave (λ) is reduced in order to improve a light resolving power of the photolithography device.

Processing methods have been developed to lower the limit of the resolving power of a device or a process. Herein, the processing methods include: using a phase inversion mask; forming a thin layer which improves an image contrast on a wafer; utilizing a triple layer photoresist method; and utilizing a sililation method.

Furthermore, a self-aligned contact (SAC) method using a hard mask layer and a landing plug contact (LPC) has been used to increase contact reliability and process stability in highly integrated devices.

FIGS. 1A and 1B are cross-sectional views illustrating a conventional method for fabricating a semiconductor device.

Referring to FIG. 1A, a gate insulation layer 12 is formed on a substrate 10, and gate electrodes are formed on the gate insulation layer 12. Herein, the gate electrodes include a poly-silicon layer 14, and a silicide layer 16 formed on the poly-silicon layer 14. Also, patterns of a hard mask layer 18 and an anti-reflective coating layer 20 are formed on the silicide layer 16. The hard mask layer 18 is made of a nitride-based material, and the anti-reflective coating layer 20 is made of an oxide-based material. Herein, predetermined portions at the top of the anti-reflective coating layer 20 and the hard mask layer 18 are removed, such that lateral walls of the anti-reflective coating layer 20 and the hard mask layer 18 are sloped.

Subsequently, a thermal treatment is performed on the above resulting substrate structure to form a thermal oxide layer 22 on exposed portions of the substrate 10, the poly-silicon layer 14, and the silicide layer 16. At this time, an abnormal oxidation occurs on a lateral wall of the silicide layer 16, and as a result, a projection is formed on the lateral wall.

Referring to FIG. 1B, an implantation process is performed. Then, a buffer oxide layer 24, an SAC nitride layer 26, and a planarizing inter-layer insulation layer (not shown) are sequentially formed on the above resulting substrate structure. Furthermore, an LPC hole is formed by performing a photolithography process using an LPC mask on a portion of the inter-layer insulation layer predetermined for a contact.

According to such conventional method for fabricating a semiconductor device, after patterning the gate electrodes, the excessive growth of the thermal oxide layer projection on the lateral wall of the silicide layer is generated during the thermal oxidation process. Thus, the nitride layer at the projection is firstly etched during a follow-up etching process, resulting in damage of the buffer oxide layer. Hence, the gate electrodes may be opened to result in short circuits with an upper line and contact defects.

### SUMMARY OF THE INVENTION

It is, therefore, an object of the present invention to provide a method for fabricating a semiconductor device including gate electrodes made up of a poly-silicon layer and a silicide layer, capable of preventing short circuits between lines and self-aligned contact (SAC) defects caused by a projection which is generated by an excessive growth of the silicide layer during a thermal oxidation process performed after patterning the gate electrodes, and thus, improving a processing yield and reliability of device operations.

In accordance with an aspect of the present invention, there is provided a method for fabricating a semiconductor device, including: forming a gate insulation layer on a substrate; forming a gate electrode on the gate insulation layer, wherein the gate electrode includes a pattern of a poly-silicon layer and a silicide layer on which a hard mask layer is superposed; recessing the silicide layer in a horizontal direction; and forming a thermal oxide layer on exposed portions of the substrate, the poly-silicon layer, and the silicide layer.

In accordance with another aspect of the present invention, there is provided a method for fabricating a semiconductor device, including: forming a gate insulation layer on a substrate; forming a gate electrode on the gate insulation layer, wherein the gate electrode includes a pattern of a poly-silicon layer and a silicide layer on which a hard mask layer is superposed; recessing the silicide layer in a horizontal direction; forming a thermal oxide layer on exposed portions of the substrate, the poly-silicon layer, and the silicide layer; and forming an anti-reflective coating layer on the hard mask layer.

### BRIEF DESCRIPTION OF THE DRAWINGS

The above and other objects and features of the present invention will become better understood with respect to the following description of the specific embodiments given in conjunction with the accompanying drawings, in which:

FIGS. 1A and 1B are cross-sectional views illustrating a conventional method for fabricating a semiconductor device; and

FIGS. 2A to 2D are cross-sectional views illustrating a method for fabricating a semiconductor device in accordance with a specific embodiment of the present invention.

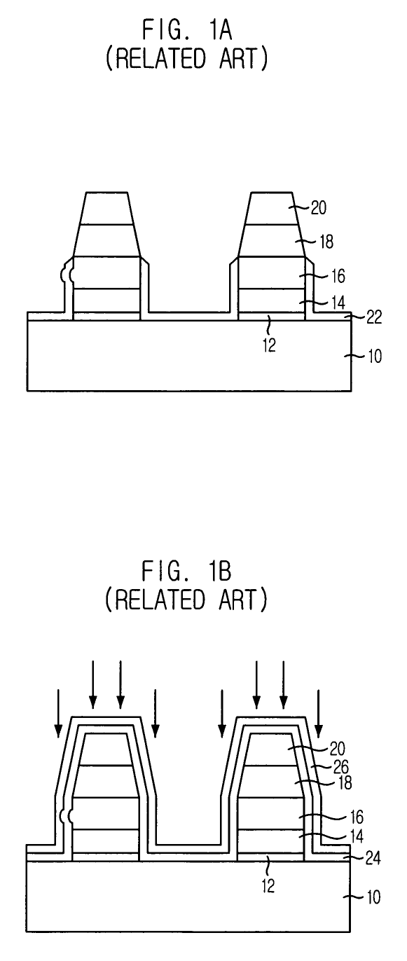

### DETAILED DESCRIPTION OF THE INVENTION

A method for fabricating a semiconductor device in accordance with specific embodiments of the present invention will be described in detail with reference to the accompanying drawings.

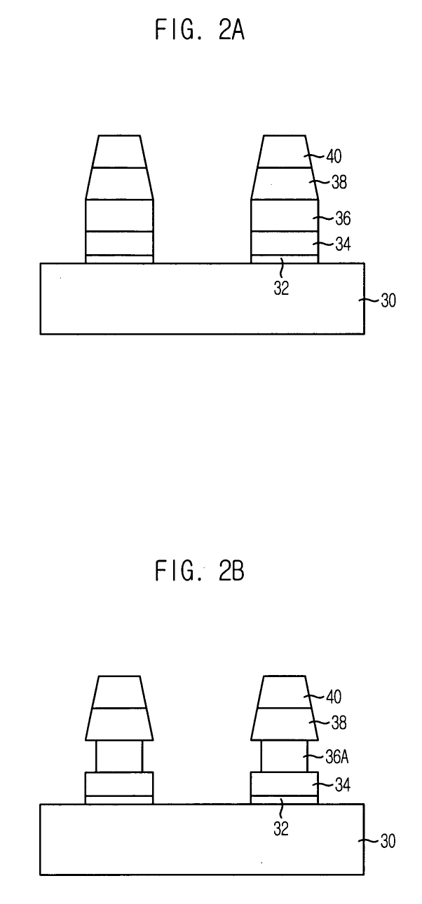

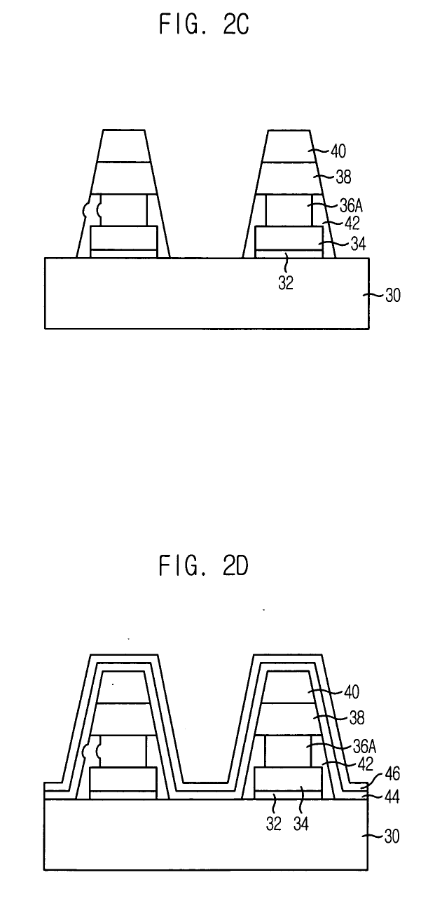

FIGS. 2A to 2D are cross-sectional views illustrating a method for fabricating a semiconductor device in accordance with a specific embodiment of the present invention.

Referring to FIG. 2A, a gate insulation layer 32 is formed on a substrate 30. Herein, the gate insulation layer 32 is formed with an oxide-based material or a nitride-based material. Then, a poly-silicon layer 34, a silicide layer 36, a hard mask layer 38, and an anti-reflective coating layer 40 are sequentially formed on the gate insulation layer 32. Herein, the hard mask layer 38 is formed with a nitride-based material, and the anti-reflective coating layer 40 is formed with silicon oxynitride (SiON). Also, the silicide layer 36 can be formed with metal silicide. Next, a photolithography process is sequentially performed on the anti-reflective coating layer 40, the hard mask layer 38, the silicide layer 36, and the poly-silicon layer 34, such that gate electrodes including patterns of the poly-silicon layer 34 and the silicide layer 36 are formed, and patterns of the hard mask layer 38 and the anti-reflective coating layer 40 are formed to superpose over the silicide layer 36.

Subsequently, a cleaning process is performed on the above resulting substrate structure with a buffered oxide etchant (BOE) solution to remove a polymer and to prevent damage on the substrate during an etching process. Herein, the BOE solution has a high etching rate toward a polymer or oxide, but has a very low etching rate toward silicide or poly-silicon, and therefore, the gate electrodes are formed with a vertical profile.

Referring to FIG. 2B, the above resulting substrate structure is dipped in a mixed solution, e.g., a mixed solution of ammonium hydroxide (NH₃OH), hydrogen peroxide (H₂O₂), and water (H₂O), to recess the silicide layer 36 in a horizontal direction as denoted with a reference numeral 36A. Herein, a ratio of H₂O to NH₃OH is greater than that of H₂O₂ to NH₃OH. More specifically, the ratio of NH₃OH to H₂O₂ to H₂O is in a range of approximately 1:2 to 5:10 to 30. The mixed solution has a higher etching rate toward the silicide layer 36 than the other layers such as the poly-silicon layer 34 or an oxide layer. At this time, an etching rate of the silicide layer 36 ranges from approximately 10 Å to approximately 20 Å per minute, and etching rates of the other layers are less than approximately 2 Å per minute.

Referring to FIG. 2C, a thermal treatment is performed on the above resulting substrate structure to form a thermal oxide layer 42 on exposed portions of the substrate 30, the poly-silicon layer 34, and the silicide layer 36A. Herein, although a projection is generated on a lateral wall of the silicide layer 36A due to excessive oxidation, the projection does not affect other processes because the lateral walls of the silicide layer 36A are previously etched.

Referring to FIG. 2D, a buffer oxide layer 44 for preventing stresses, a nitride layer 46 for functioning as an etch barrier, and an inter-layer insulation layer (not shown) for functioning as a planarizing layer are sequentially formed on the above resulting substrate structure. Then, a landing plug contact (LPC) hole is formed by performing a photolithography using an LPC mask to remove a portion of the inter-layer insulation layer predetermined for a contact. Herein, only a small portion of the projection protrudes externally due to the previously recessed silicide layer in the horizontal direction, and thus, the projection cannot affect the patterns during a follow-up etching process or implantation process.

In accordance with the specific embodiment of the present invention, a processing yield and reliability of the device can be improved by: forming the gate electrodes made of the patterns of the poly-silicon layer and the silicide layer, with the pattern of the hard mask layer superposed over; recessing the silicide layer in the horizontal direction, such that the projection generated by the excessive growth of the silicide layer during the thermal treatment process cannot affect the follow-up processes, preventing short circuits between lines or contact defects.

The present application contains subject matter related to the Korean patent application No. KR 2005-0058520, filed in the Korean Patent Office on Jun. 30, 2005, the entire contents of which being incorporated herein by reference.

While the present invention has been described with respect to certain specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a gate insulation layer on a substrate;
forming a gate electrode on the gate insulation layer, wherein the gate electrode includes a pattern of a poly-silicon layer and a silicide layer on which a hard mask layer is superposed;
recessing the silicide layer in a horizontal direction; and
forming a thermal oxide layer on exposed portions of the substrate, the poly-silicon layer, and the silicide layer.

2. The method of claim 1, wherein the recessing of the silicide layer in the horizontal direction is performed by employing a mixed solution of ammonium hydroxide (NH₃OH), hydrogen peroxide (H₂O₂), and water (H₂O).

3. The method of claim 2, wherein a ratio of H₂O to NH₃OH is greater than that of H₂O₂ to NH₃OH.

4. The method of claim 3, wherein the minimum ratio of H₂O to NH₃OH is at least twice the maximum ratio of H₂O₂ to NH₃OH.

5. The method of claim 4, wherein the ratio of H₂O₂ to NH₃OH is in a range of approximately 2 to 5:1.

6. The method of claim 4, wherein the ratio of H₂O to NH₃OH is in a range of approximately 10 to 30:1.

7. The method of claim 1, wherein a recessing rate of the silicide layer ranges from approximately 10 Å to approximately 20 Å per minute.

8. A method for fabricating a semiconductor device, comprising:
forming a gate insulation layer on a substrate;
forming a gate electrode on the gate insulation layer, wherein the gate electrode includes a pattern of a poly-silicon layer and a silicide layer on which a hard mask layer is superposed;
recessing the silicide layer in a horizontal direction;
forming a thermal oxide layer on exposed portions of the substrate, the poly-silicon layer, and the silicide layer; and
forming an anti-reflective coating layer on the hard mask layer.

9. The method of claim 8, wherein the recessing of the silicide layer in the horizontal direction is performed by employing a mixed solution of ammonium hydroxide (NH₃OH), hydrogen peroxide (H₂O₂), and water (H₂O).

10. The method of claim 9, wherein a ratio of H₂O to NH₃OH is greater than that of H₂O₂ to NH₃OH.

11. The method of claim 10, wherein the minimum ratio of H₂O to NH₃OH is at least twice the maximum ratio of H₂O₂ to NH₃OH.

12. The method of claim 11, wherein the ratio of H₂O₂ to NH₃OH is in a range of approximately 2 to 5:1.

13. The method of claim 11, wherein the ratio of H₂O to NH₃OH is in a range of approximately 10 to 30:1.

14. The method of claim 8, wherein a recessing rate of the silicide layer ranges from approximately 10 Å to approximately 20 Å per minute.
